(19) United States
(12) Patent Application Publication
(10) Pub. No.: US 2014/0246584 A1
(43) Pub. Date: Sep. 4, 2014

(54) SCANNING ELECTRON MICROSCOPE

(71) Applicant: Samsung Electronics Co., Ltd., Suwon-Si (KR)

(72) Inventors: Jeong-Woo HYUN, Suwon-si (KR); Won-Guk SEO, Gunpo-si (KR); Chang-Hoon CHOI, Suwon-si (KR); Byeong-Hwan JEON, Yongin-si (KR)

(73) Assignee: SAMSUNG ELECTRONICS CO., LTD., Suwon-Si (KR)

(21) Appl. No.: 14/060,783

(22) Filed: Oct. 23, 2013

(30) Foreign Application Priority Data
Mar. 4, 2013 (KR) 10-2013-0022906

(51) Int. Cl. H01J 37/26; H01J 37/20

(52) U.S. Cl. CPC H01J 37/263; H01J 37/20; H01J 37/26
USPC 250/310

(57) ABSTRACT

Provided is a scanning electron microscope capable of collecting electric charges accumulated on a sample. The scanning electron microscope includes a column unit configured to generate an electron beam and scan a sample with the electron beam, a chamber unit combined with the column unit, and including a sample stage spaced apart from an end of the column unit to accommodate the sample therein, a detection unit configured to detect signals emitted from the sample, a charge collecting unit disposed between the end of the column unit and the sample stage to collect electric charges, and a voltage supply unit configured to apply an optimum or, alternatively, desirable voltage to the charge collecting unit.

### CROSS-REFERENCE TO RELATED APPLICATION

This application claims priority under 35 U.S.C. §119 to Korean Patent Application No. 10-2013-0022906 filed on Mar. 4, 2013, the disclosure of which is hereby incorporated by reference in its entirety.

### BACKGROUND

1. Field

Some embodiments of the inventive concepts relate to a scanning electron microscope capable of collecting electric charges accumulated on a surface of a sample.

2. Description of Related Art

As patterns of semiconductor devices have decreased in size, the resolutions of scanning electron microscopes have become important and various methods have thus been introduced to improve the resolutions.

### SUMMARY

At least one embodiment of the inventive concepts provide a scanning electron microscope in which a charge collecting unit is disposed between a column unit and a sample stage to collect electric charges accumulated on a surface of a sample.

At least one embodiment of the inventive concepts also provide a scanning electron microscope in which an optimum or, alternatively, desirable voltage is applied to a charge collecting unit according to the type of a sample so as to maximize or, alternatively, increase the rate of collecting electric charges accumulated on a surface of the sample, thereby improving the quality of images of the sample.

At least one embodiment of the inventive concepts also provide a scanning electron microscope in which the height of a charge collecting unit is adjusted to minimize or, alternatively, reduce the distance between the charge collecting unit and a sample so as to maximize or, alternatively, increase the rate of collecting electric charges accumulated on a surface of the sample, thereby improving the quality of images of the sample.

The technical objectives of at least some of the embodiment of the inventive concepts are not limited to the above disclosure; other objectives may become apparent to those of ordinary skill in the art based on the following descriptions.

In accordance at least one embodiment of the inventive concepts, a scanning electron microscope may include a column unit configured to generate an electron beam and scan the electron beam on a sample, a chamber unit combined with the column unit, and including a sample stage spaced apart from an end of the column unit to accommodate the sample therein, a detection unit configured to detect signals emitted from the sample, a charge collecting unit disposed between the end of the column unit and the sample stage to collect electric charges, and a voltage supply unit configured to apply an optimum or, alternatively, desirable voltage to the charge collecting unit according to the type of the sample.

In accordance with at least one embodiment of the inventive concepts, a scanning electron microscope may include a column unit configured to generate an electron beam, a chamber unit having an upper portion into which an end of the column unit is inserted, a voltage supply unit configured to apply a (+), or positive, voltage to the charge collecting unit; and a height adjustment unit configured to adjust a distance between the charge collecting unit and the sample stage. The chamber unit includes a sample stage disposed at a bottom of the chamber unit, a detection unit disposed between the column unit and the sample stage to detect a signal, and a charge collecting unit disposed between the detection unit and the sample stage to collect electric charges.

In accordance with at least one embodiment of the inventive concepts, a scanning electron microscope (SEM) may include a sample stage configured to hold a sample; a column unit configured to generate an electron beam such that the electron beam irradiates the sample; a detection unit configured to detect first signals, the first signals being signals emitted from the sample in response to the irradiation; and a charge collecting unit configured to collect first charges, the first charges being charges accumulated on a surface of the sample, the charge collecting unit being disposed between the sample stage and the column unit.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a schematic block diagram of a scanning electron microscope in accordance with an embodiment of the inventive concepts;

FIG. 2 is a perspective view of an example of a charge collecting unit of FIG. 1;

FIGS. 3A to 3F are perspective views of various examples of a bias unit illustrated in FIG. 2;

FIG. 4A is a diagram illustrating a support unit in accordance with an embodiment of the inventive concepts;

FIG. 4B is a diagram illustrating a height adjustment unit and the support unit in accordance with an embodiment of the inventive concepts;

FIG. 4C is a diagram illustrating a control unit and the support unit in accordance with another embodiment of the inventive concepts;

FIGS. 5A to 5C are diagrams schematically showing the flow of electrons according to whether a charge collecting unit is used or not;

FIGS. 6A to 6F illustrate line profile images and histograms obtained according to whether the charge collecting unit is used or not; and

FIGS. 7A to 7C illustrate images of a sample obtained according to voltages applied to a charge collecting unit in accordance with at least one example embodiment of the inventive concepts.

### DETAILED DESCRIPTION OF THE EMBODIMENTS

Advantages and characteristics of the inventive concepts and a method of achieving them will be apparent from embodiments described in detail with reference to the accompanying drawings below. The inventive concepts is, however, not limited to the embodiments set forth herein and may be embodied in different forms. Rather, these embodiments are provided so that this disclosure is thorough and complete and fully conveys the inventive concepts to those skilled in the art. The spirit and scope of the inventive concepts is defined by the appended claims.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The same reference numerals refer to the same elements throughout the present disclosure. Thus, even if the same or like reference numerals are not mentioned or described in a drawing, they may be described with reference to another drawing. Also, even if an element is not assigned a reference numeral, this element may be described with reference to other drawings.

Accordingly, while example embodiments are capable of various modifications and alternative forms, embodiments are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

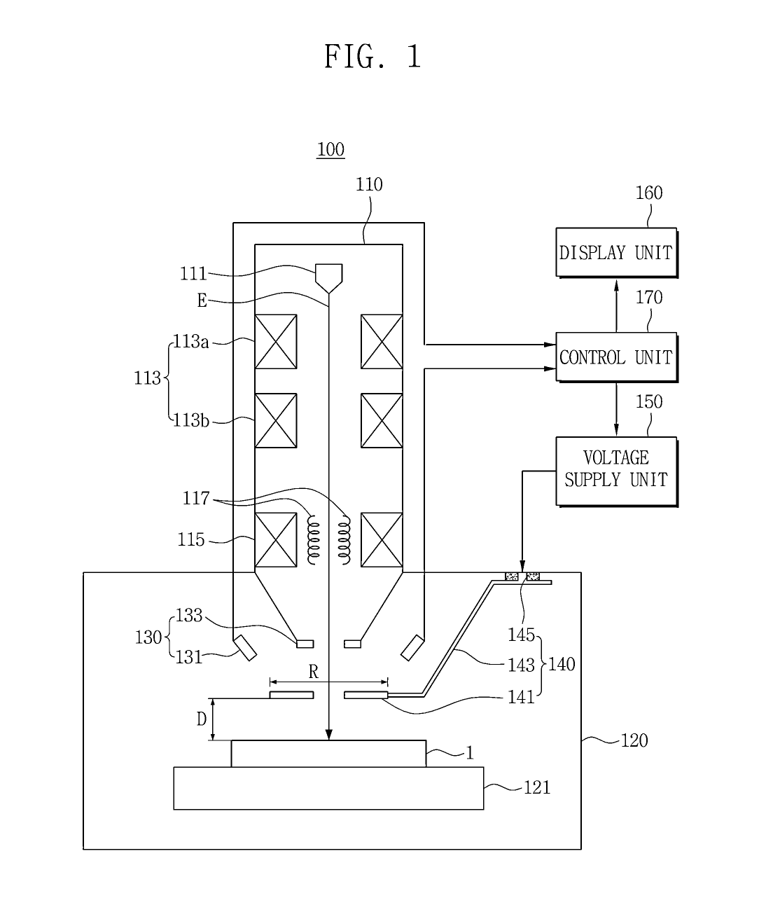

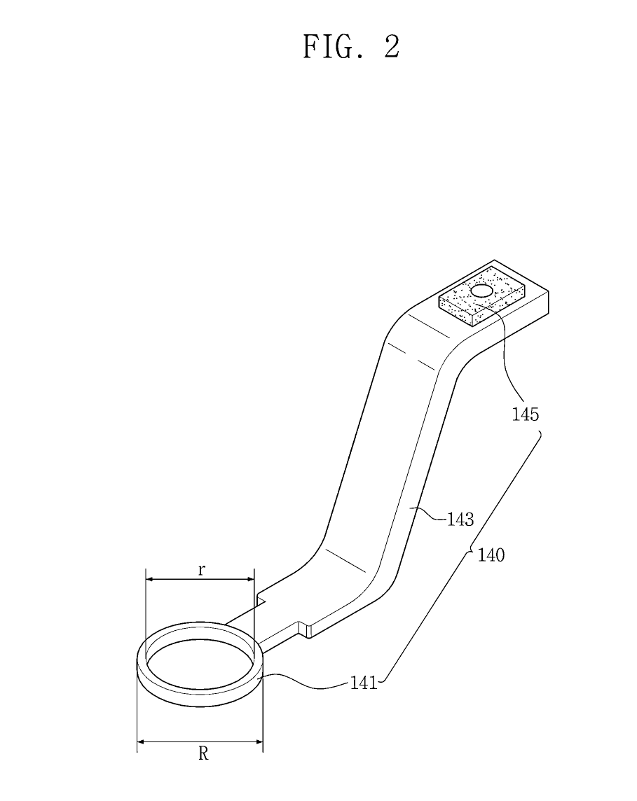

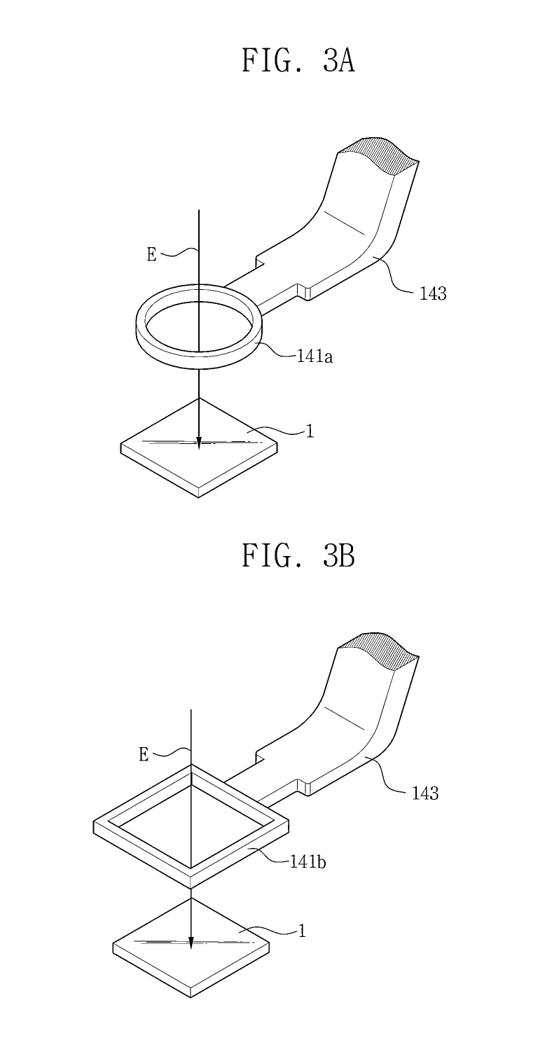

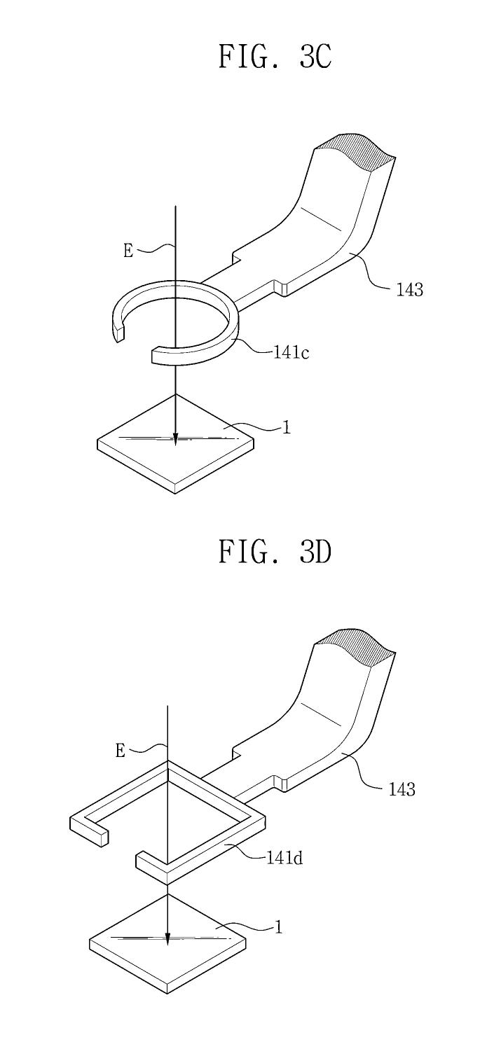

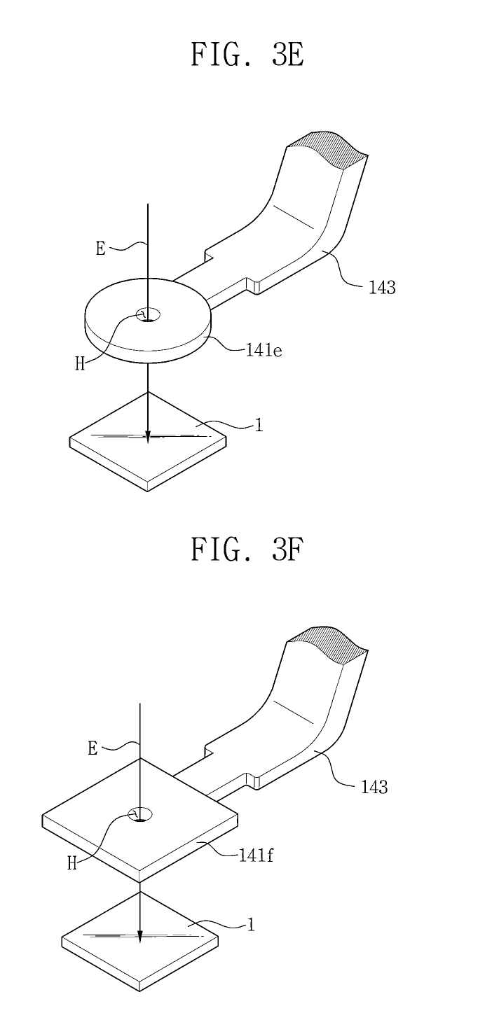

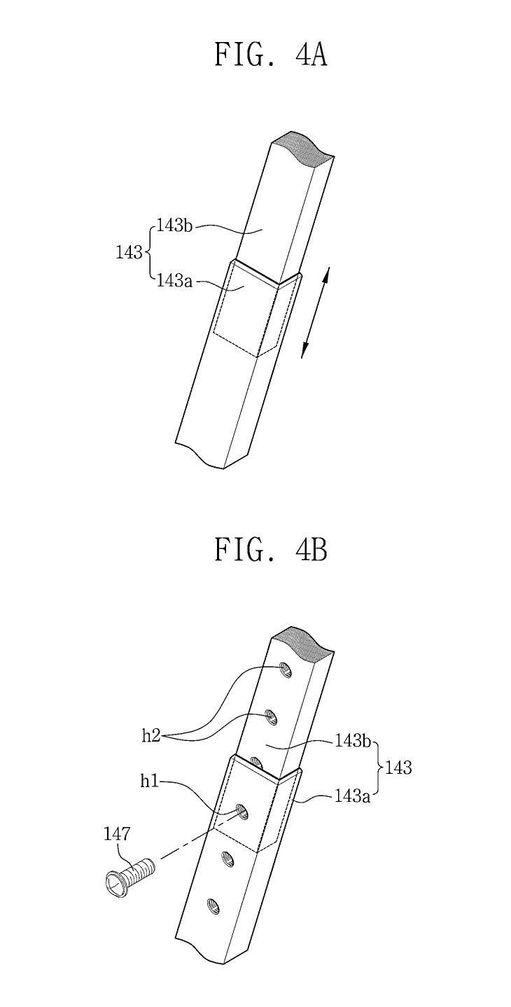

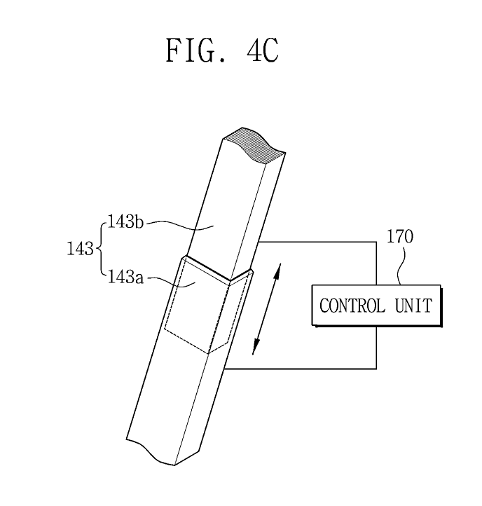

FIG. 1 is a schematic block diagram of a scanning electron microscope (SEM) 100 in accordance with an embodiment of the inventive concepts. FIG. 2 is a perspective view of an example of a charge collecting unit 140 of FIG. 1. FIGS. 3A to 3F are perspective views of various examples of a bias unit 141 illustrated in FIG. 2. FIG. 4A is a diagram illustrating a support unit 143 in accordance with an embodiment of the inventive concepts. FIG. 4B is a diagram illustrating a height adjustment unit 147 and the support unit 143 in accordance with an embodiment of the inventive concepts. FIG. 4C is a diagram illustrating a control unit and the support unit 143 in accordance with another embodiment of the inventive concepts;

Referring to FIG. 1, the SEM 100 irradiates a sample 1 with an electron beam E, detects various signals emitted from the sample 1 through an interaction between the sample 1 and the electron beam E, and transforms the various signals into an image. The SEM 100 may include a column unit 110, a chamber unit 120, a charge collecting unit 140, a voltage supply unit 150, a display unit 160, and a control unit 170. Here, the various signals emitted from the sample 1 by irradiating the sample 1 with the electron beam E may include, for example, secondary electrons (SE), back scattered electrons (BSE), an X-ray, a visible ray, cathode fluorescent light, etc.

The column unit 110 may generate, accelerate, and condense an electron beam E, and then irradiate the sample 1 with the condensed electron beam E. As illustrated in FIG. 1, the column unit 110 is manufactured in the form of a body tube and is electrically grounded. An electron gun 111, a condensing lens 113, an objective lens 115, scanning coils 117, etc., may be included in the body tube.

The electron gun 111 may generate an electron beam E to irradiate the sample 1, and accelerate the electron beam E. For example, the electron gun 111 may generate an electron beam E by generating electrons by heating a filament formed of tungsten (W) or the like, and may accelerate the electron beam E with about several tens of keV of energy by applying a voltage to the electrons.

The condensing lens 113 may condense the electron beam E, which is generated and accelerated by the electron gun 111, on a fine point on the sample 1. The smaller the diameter of the electron beam E with which the sample 1 is irradiated, the higher the resolution of an image of the sample 1, which is obtained from the signals emitted from the sample 1 by the electron beam E, may be. A plurality of condensing lenses 113 may be used to condense the diameter of the electron beam E in stages so as to increase the resolution of an image of the sample 1. For example, as illustrated in FIG. 1, the condensing lens 113 may include a first condensing lens 113a for primarily condensing the electron beam E generated and accelerated by the electron gun 111, and a second condensing lens 113b for secondarily condensing the electron beam E condensed by the first condensing lens 113a. Though only two condensing lenses 113a and 113b are illustrated in the example included in FIG. 1, any number of condensing lenses may be included in the SEM 100. The diameter of the electron beam E after being condensed by the second condensing lens 113b may be less than that of the electron beam E after being condensed by the first condensing lens 113a. The diameter of the electron beam E condensed by the condensing lens 113 may be several tens of nm.

The objective lens 115 may focus the electron beam E condensed by the condensing lens 113 on the sample 1. For example, the objective lens 115 may determine the size of the electron beam E with which the sample 1 is irradiated, and may be located adjacent to a surface of the sample 1 to shorten a focal length so that the electron beam E may have a shorter diameter. In other words, the shorter the distance between the objective lens 115 and the surface of the sample 1 (hereinafter referred to as a ‘working distance’), the smaller a spot of the electron beam E may be. As described above, the objective lens 115 may adjust the resolution (magnification) of an image of the sample 1 by adjusting the diameter of the electron beam E.

The scanning coils 117 may adjust an angle and direction in which the electron beam E radiates so that the entire sample 1 may be irradiated with the electron beam E to scan the sample 1. For example, when current is supplied to the scanning coils 117, the entire sample 1 may be irradiated with the electron beam E in an x-axis direction and a y-axis direction to scan the sample 1. Specifically, when current is supplied to the scanning coils 117, the electron beam E may bend. Thus, the degree to which the electron beam E bends may be controlled according to the intensity of the current supplied to the scanning coils 117, and the direction in which the electron beam E bends may be controlled according to the direction of the current supplied. Thus, an angle and direction in which the electron beam E radiates may be controlled by adjusting the intensity and direction of the current supplied to the scanning coils 117. The scanning coils 117 may be, for example, deflection coils.

The chamber unit 120 may be combined with the column unit 110 such that an end of the column unit 110 is inserted into an upper portion of the chamber unit 120, and may accommodate the sample 1 spaced apart from the end of the column unit 110. The chamber unit 120 is shaped as a hexahedron, is electrically grounded as illustrated in FIG. 1, and may include a sample stage 121 to support the sample 1 such that the sample 1 is located below the charge collecting unit 140.

The detection unit 130 may detect various signals that are emitted from the sample 1 as a result of the electron beam E irradiating the sample 1. In detail, when the sample 1 is irradiated with the electron beam E, the detection unit 130 may detect various signals emitted from the sample 1 through an interaction between the sample 1 and the electron beam E. The detection unit 130 may include a plurality of detectors 131 and 133 configured to respectively detect corresponding signals among the various signals emitted from the sample 1 as illustrated in FIG. 1. For example, the detection unit 130 may include the first detector 131 for detecting secondary electrons (SE) and the second detector 133 for detecting back scattered electrons (BSE) among signals emitted from the sample 1 by irradiating the sample 1 with the electron beam E.

The first and second detectors 131 and 133 of the detection unit 130 may be installed in the column unit 110 or the chamber unit 120. Also, since the amounts of and a ratio of the various signals, including the secondary electrons (SE) and the back scattered electrons (BSE), emitted from the sample 1 may vary according to the type of the sample 1 to be tested and the intensity and angle of the electron beam E with which the sample 1 is irradiated, one or both of the first detector 131 and the second detector 133 of the detection unit 130 may be selected and used individually or simultaneously.

The charge collecting unit 140 may be disposed between the end of the column unit 110 and the sample stage 121 to draw and collect electric charges accumulated on a surface of the sample 1 when the sample 1 is irradiated with the electron beam E irradiated from the column unit 110.

An optimum or, alternatively, desirable voltage may be applied to the charge collecting unit 140 according to the type of the sample 1. When an optimum or, alternatively, desirable voltage is applied to the charge collecting unit 140 according to the type of the sample 1, an electric field may be formed between the charge collecting unit 140 and the sample 1 to more effectively draw electric charges accumulated on a surface of the sample 1 by the charge collecting unit 140, thereby maximizing or, alternatively, increasing the rate of collecting the electric charges accumulated on the surface of the sample 1.

The charge collecting unit 140 may include a bias unit 141 and a support unit 143 as illustrated in FIG. 2.

The bias unit 141 may be disposed between the end of the column unit 110 and the sample stage 121 (particularly, between the detection unit 130 and the sample stage 121) to collect electric charges on a surface of the sample 1 according to an optimum or, alternatively, desirable voltage applied based on the type of the sample 1. The shape and size (R, r) of the bias unit 141 may vary according to the size and shape of the sample 1 and the location of the detection unit 130.

For example, the bias unit 141 may be formed as a ring type bias unit 141a or 141b as illustrated in FIG. 3A or 3B. The one or both of the ring type bias units 141a and 141b may have a circular shape, a rectangular shape, or a polygonal shape.

Otherwise, the bias unit 141 may be formed as a horseshoe type bias unit 141c or 141d, a portion of which is open as illustrated in FIG. 3C or 3D. Similarly, one or both of the horseshoe type bias units 141c and 141d may have a circular shape, a rectangular shape, or a polygonal shape.

Otherwise, the bias unit 141 may be formed as a plate type bias unit 141e or 141f having a hole H through which the electron beam E passes as illustrated in FIG. 3E or 3F. Similarly, one or both of the plate type bias unit 141e and 141f may have a circular shape, a rectangular shape, or a polygonal shape.

The bias unit 141 may include a metal, for example, steel use stainless (SUS).

The support unit 143 may have one end connected to the bias unit 141 and another end fixed on the column unit 110 or the chamber unit 120 to support the bias unit 141.

As illustrated in FIG. 4A, the support unit 143 may include the first support 143a and a second support 143b. In FIG. 4A, only portions of the first support 143a and the second support 143b are shown. According to at least some example embodiments of the inventive concepts, the first support 143a may have a first end connected to the bias unit 141, and a second end inserted into the second support 143b, and the second support 143b may have a first end fixed on a portion of the column unit 110 or the chamber unit 120, and a second end into which the second end of the first support 143a is inserted such that the first support 143a may slide upward/downward along the second support 143b. Alternatively, the second support 143b may be inserted into the first support 143a so that the second support 143b may slide upward/downward.

As illustrated FIG. 4B, the first support 143a includes a plurality of first height adjustment holes h1 formed longitudinally in upper portion of the first support 143a, and the second support 143b includes a plurality of second height adjustment holes h2 formed longitudinally in lower portion of the second support 143b to correspond, to and overlap with, the plurality of first height adjustment holes h1.

Also, as is illustrated in FIG. 1, the charge collecting unit 140 may further include insulating units 145 configured to electrically insulate the support unit 143 and either the column unit 110 or the chamber unit 120 when the support unit 143 is fixed on a portion of the column unit 110 or the chamber unit 120 that is electrically grounded.

The scanning electron microscope 100 in accordance with an embodiment of the inventive concepts may further include the height adjustment unit 147 configured to adjust a distance D between the charge collecting unit 140 and the sample 1 according to the height of the sample 1.

For example, as illustrated FIG. 4B, the height adjustment unit 147 may include a height fastener configured to fix one of the plurality of first height adjustment holes h1 and one of the plurality of the second height adjustment holes h2 corresponding to the first height adjustment holes h1 while passing through the first height adjustment hole h1 and the second height adjustment hole h2 so that the heights of the first and second supports 143a and 143b may be adjusted in incremental steps. For example, the height fastener may be, for example, a bolt, a screw, or a stud.

Also, as illustrated in FIG. 4C, the first and second supports 143a and 143b may be electrically connected to the control unit 170 so as to electrically slide with respect to each other under control of the control unit 170, thereby adjusting the distance D between the bias unit 141 and the sample 1.

Through the height adjustment unit 147, the distance D between the charge collecting unit 140, for example, the bias unit 141, and the sample 1 may be adjusted. The shorter the distance D, the higher the rate of collecting electric charges accumulated on a surface of the sample 1.

The voltage supply unit 150 may apply an optimum or, alternatively, desirable voltage to the charge collecting unit 140, for example, the bias unit 141, according to the type of the sample 1. An optimum or, alternatively, desirable voltage is a voltage, for example, a (+), or positive, voltage, that enables the electric charges accumulated on the surface of the sample 1 to be drawn at a maximum or, alternatively, relatively high level. In other words, an optimum or, alternatively, desirable voltage is a voltage corresponding to an image having a highest contrast among a plurality of images of the sample 1 which are obtained from the sample 1 when a plurality of different voltages are applied to the bias unit 141 of the charge collecting unit 140. An optimum or, alternatively, desirable voltage may be set during device design or when needed.

The control unit 170 may control overall operations of the scanning electron microscope 100 in accordance with an embodiment of the inventive concepts.

The control unit 170 may cause signals detected by the detection unit 130 to be transformed into image signals and cause the image signals to be displayed on the display unit 160 by, for example, controlling the detection unit 130 and the display unit 160 using control signals. Also, the control unit 170 may control the voltage supply unit 150 to apply an optimum or, alternatively, desirable voltage to the bias unit 141 of the charge collecting unit 140 according to the type of the sample 1. That is, the control unit 170 may control the voltage supply unit 150 to apply an optimum or, alternatively, desirable voltage to the bias unit 141 of the charge collecting unit 140 according to the type of the sample 1 so as to maximize or, alternatively, increase the rate of collecting electric charges accumulated on the surface of the sample 1, thereby improving the resolution of the images of the sample 1 displayed on the display unit 160.

The control unit 170 may also electrically control the height adjustment unit 147 to minimize or, alternatively, reduce the distance D between the bias unit 141 and the sample 1 according to the height of the sample 1 as illustrated in FIG. 4C. In other words, the control unit 170 may electrically control to minimize or, alternatively, reduce the distance D between the bias unit 141 and the sample 1 so as to maximize or, alternatively, increase the rate of collecting electric charges accumulated on a surface of the sample 1, thereby improving the resolution of images of the sample 1 displayed on the display unit 160.

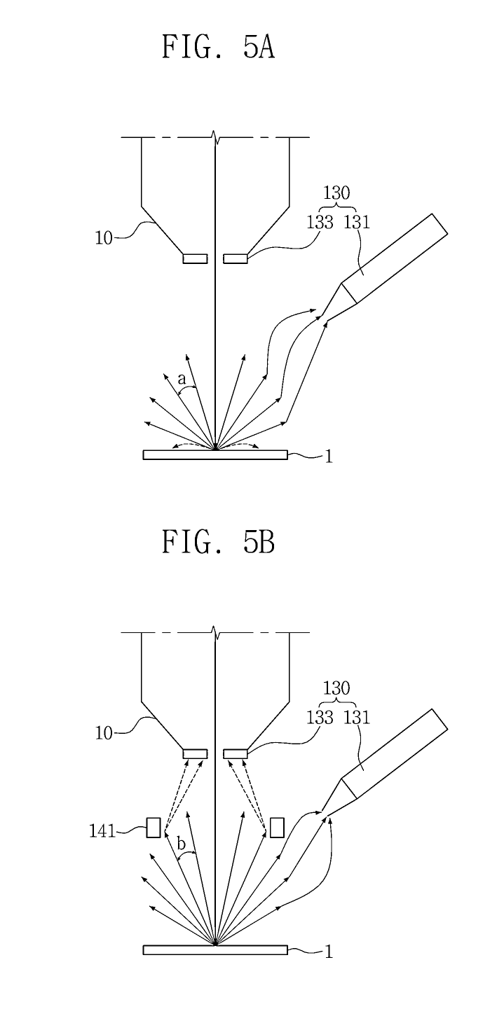

FIGS. 5A to 5C are diagrams schematically showing the flow of electrons according to whether the charge collecting unit 140 is used or not

Specifically, FIG. 5A illustrates the flow of electrons when the charge collecting unit 140 in accordance with an embodiment of the inventive concepts is not used. FIG. 5B illustrates the flow of electrons when a voltage is not applied to the charge collecting unit 140 in accordance with an embodiment of the inventive concepts. FIG. 5C illustrates the flow of electrons when a voltage, e.g. about 200 V, is applied to the charge collecting unit 140 in accordance with an embodiment of the inventive concepts.

The charge collecting unit 140 in accordance with an embodiment of the inventive concepts may not only collect electric charges accumulated on a surface of the sample 1 but also electrons emitted from the sample 1 (e.g., secondary electrons (SE) or back scattered electrons (BSE)) and lower the divergence of electrons to draw the electric charges to the detection unit 130 or to enable the detection unit 130 to detect more electrons.

Referring to FIGS. 5A to 5C, the charge collecting unit 140 draws electrons having low energy and falling onto the sample 1 (indicated with dotted lines) among electrons emitted from the sample 1 illustrated in FIG. 5A to the detection unit 130 as illustrated in FIGS. 5B and 5C.

Also, the divergence of the electrons emitted from the sample 1 becomes lower in the order of FIGS. 5A to 5C (that is, a>b>c). In other words, the divergence of the electrons is much lower when the charge collecting unit 140 is used than when the charge collecting unit 140 is not used, and is much lower when a voltage (e.g., an optimum or, alternatively, desirable voltage according to the type of the sample 1) is applied to the charge collecting unit 140 than when no voltage is applied to the charge collecting unit 140.

This is because when an optimum or, alternatively, desirable voltage is applied to the bias unit 114 of the charge collecting unit 140 according to the type of the sample 1, the electrons emitted from the sample 1 due to an electric field formed between the bias unit 141 and the sample 1 are drawn to the bias unit 141. The lower the divergence of the electrons, the more electrons are detected by the detection unit 130, and the higher the resolution of images of the sample 1.

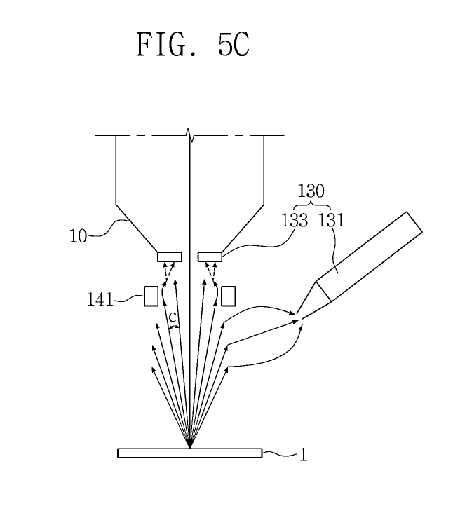

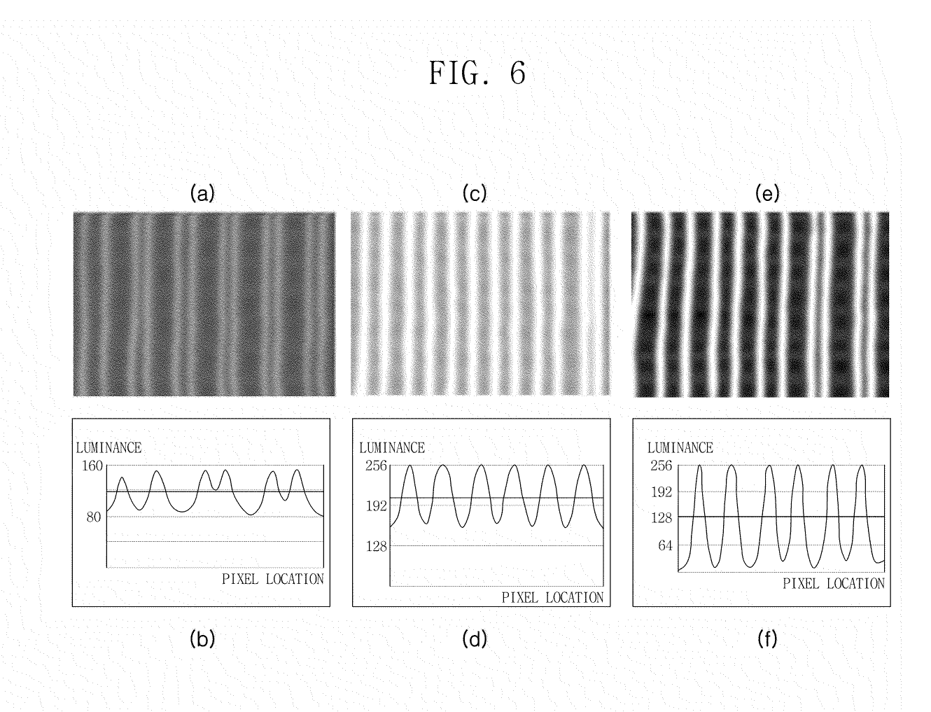

FIGS. 6A to 6F illustrate line profile images and histograms obtained according to whether the charge collecting unit 140 is used or not. Here, the histograms show the rate of collecting electric charges for respective pixels of a line profile image with luminance levels ranging from 0 to 256, in which the X-axis denotes the locations of the pixels and the Y-axis denotes the luminance levels.

Specifically, FIGS. 6A and 6B illustrate line profile images and histograms obtained when the charge collecting unit 140 is not used. FIGS. 6C and 6D illustrate line profile images and histograms obtained when the charge collecting unit 140 is used and a voltage is not applied thereto. FIGS. 6E and 6F illustrate line profile images and histograms obtained when the charge collecting unit 140 is used and a voltage, for example about 200 V, is applied thereto.

Referring to FIGS. 6A to 6F, the difference between a maximum luminance level and a minimum luminance level, i.e., a contrast, is higher when the charge collecting unit 140 in accordance with an embodiment of the inventive concepts is used (as is shown in FIGS. 6C and 6D or FIGS. 6E and 6F) than when the charge collecting unit 140 is not used (as is shown in FIGS. 6A and 6B), thereby obtaining a clearer image.

Also, the contrast is higher when a voltage is applied to the charge collecting unit 140 in accordance with an embodiment of the inventive concepts (as is shown in FIGS. 6E and 6F) than when a voltage is not applied to the charge collecting unit 140 in accordance with an embodiment of the inventive concepts (as is shown in FIGS. 6C and 6D), thereby obtaining a clearer image.

This means that electric charges accumulated on a surface of the sample 1 may be collected by the charge collecting unit 140, and the rate of collecting the electric charges accumulated on the surface of the sample 1 may be increased when a voltage is applied to the charge collecting unit 140.

In this case, when an optimum or, alternatively, desirable voltage is applied to the charge collecting unit 140 according to the type of the sample 1, an amount of uncollected electric charges accumulated on the surface of the sample 1 may be minimized or, alternatively, reduced, because, for example, the rate of collecting the electric charges accumulated on the surface of the sample 1 may be maximized or, alternatively, increased.

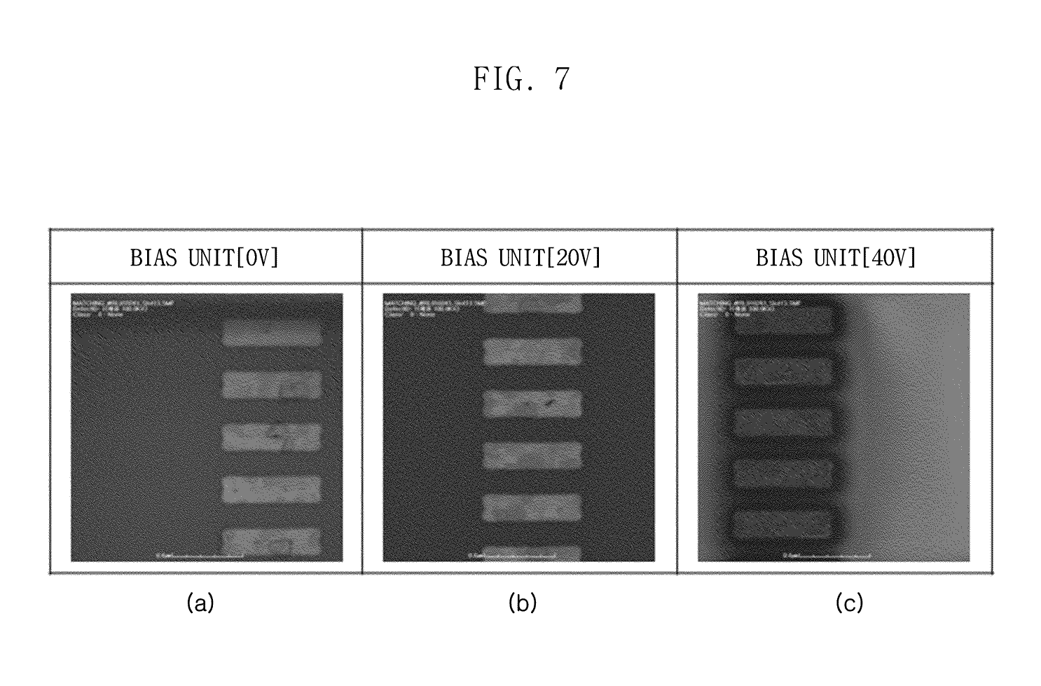

FIGS. 7A to 7C illustrate images of a sample obtained according to voltages applied to the charge collecting unit 140 in accordance with at least some embodiments of the inventive concepts.

Specifically, FIG. 7A illustrates an image of a sample obtained when 0 V is applied to the charge collecting unit 140. FIG. 7B illustrates an image of the sample obtained when 20 V is applied to the charge collecting unit 140. FIG. 7C illustrates an image of the sample obtained when 40 V is applied to the charge collecting unit 140.

Referring to FIGS. 7A to 7C, the image of the sample illustrated in FIG. 7A obtained when 20 V is applied to the charge collecting unit 140 is clearer than both i) the image of the sample illustrated in FIG. 7B when 0 V is applied to the charge collecting unit 140 and ii) the image of the sample illustrated in FIG. 7C when 40V is applied to the charge collecting unit 140. Accordingly, in the example illustrated in FIGS. 7A-7C, 20V represents an optimum or, alternatively, desirable voltage while 0V and 40V represent voltages which are too low and too high, respectively.

This means a voltage selected according to the type of the sample 1 is an optimum or, alternatively, desirable voltage that maximizes or, alternatively, increases the rate of collecting electric charges by the charge collecting unit 140. In other words, an amount of uncollected electric charges accumulated on the surface of the sample 1 may be minimized or, alternatively, reduced by applying an optimum or, alternatively, desirable voltage to the charge collecting unit 140 according to the type of the sample 1.

As described above, in a scanning electron microscope in accordance with an embodiment of the inventive concepts, a charge collecting unit may be disposed between an end of a column unit and a sample stage and an optimum or, alternatively, desirable voltage may be applied to the charge collecting unit according to the type of a sample so as to maximize or, alternatively, increase the rate of collecting electric charges on a surface of a sample, thereby improving the quality of images of the sample.

Also, the height of the charge collecting unit may be adjusted according to the height of the sample to minimize or, alternatively, reduce the distance D between the charge collecting unit and the sample, thereby maximizing or, alternatively, increasing the rate of collecting electric charges accumulated on a surface of the sample. Accordingly, the quality of images of the sample may be improved.

Also, one of various-shaped charge collecting units, e.g., a ring type, a horseshoe type, a plate type, etc., is selected and disposed according to the location of a detection unit or according to the type, size, and shape of the sample so that detection of various signals emitted from the sample by irradiating the sample with an electron beam may not be interrupted by a charge collecting unit, thereby obtaining a high-quality image of the sample.

The foregoing is illustrative of embodiments and is not to be construed as limiting thereof. Although a few embodiments have been described, those skilled in the art will readily appreciate that many modifications are possible with respect to the embodiments without materially departing from the novel teachings and advantages, and all such modifications as would be obvious to one skilled in the art are intended to be included within the scope of the following claims. Accordingly, all such modifications are intended to be included within the scope of these inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A scanning electron microscope comprising:
a column unit configured to generate an electron beam and scan a sample with the electron beam;
a chamber unit combined with the column unit, the chamber unit including a sample stage spaced apart from an end of the column unit such that the sample can fit in the sample stage;
a detection unit configured to detect signals emitted from the sample;
a charge collecting unit disposed between the end of the column unit and the sample stage, the charge collecting unit being configured to collect electric charges; and
a voltage supply unit configured to apply a voltage to the charge collecting unit.

2. The scanning electron microscope of claim 1, wherein the column unit comprises:
an electron gun configured to generate and accelerate the electron beam;
a plurality of condensing lenses configured to condense the electron beam;
an objective lens configured to focus the electron beam condensed by the plurality of condensing lenses on the sample; and
scanning coils configured to control an angle and direction of the focused electron beam with respect to the scanning of the sample.

3. The scanning electron microscope of claim 1, wherein the detection unit comprises:
a first detector configured to detect secondary electrons emitted from the sample; and
a second detector configured to detect back scattered electrons emitted from the sample.

4. The scanning electron microscope of claim 1, wherein the charge collecting unit is disposed between the detection unit and the sample stage.

5. The scanning electron microscope of claim 4, wherein the charge collecting unit comprises:
a bias unit configured to collect electric charges accumulated on a surface of the sample according to the voltage applied to the charge collecting unit by the voltage supply unit; and
a support unit configured to support the bias unit, the support unit including a first end connected to the bias unit, and a second end fixed on at least one of the column unit and a portion of the chamber unit.

6. The scanning electron microscope of claim 5, wherein the charge collecting unit further comprises:
an insulating unit configured to provide electrical insulation between the support unit and at least one of the column unit and the chamber unit.

7. The scanning electron microscope of claim 5, wherein the bias unit is formed as a ring type, a horseshoe type, or a plate type.

8. The scanning electron microscope of claim 5, wherein the bias unit has a circular shape, a rectangular shape, or a polygonal shape.

9. The scanning electron microscope of claim 5, wherein the bias unit includes a metal.

10. A scanning electron microscope comprising:
a column unit configured to generate an electron beam;
a chamber unit having an upper portion into which an end of the column unit is inserted, the chamber unit including,
a sample stage disposed at a bottom of the chamber unit;
a detection unit configured to detect a signal, the detection unit being disposed between the column unit and the sample stage; and
a charge collecting unit configured to collect electric charges, the charge collecting unit being disposed between the detection unit and the sample stage;
a voltage supply unit configured to apply a positive voltage to the charge collecting unit; and
a height adjustment unit configured to adjust a distance between the charge collecting unit and the sample stage.

11. The scanning electron microscope of claim 10, wherein the charge collecting unit comprises:
a bias unit configured to collect electric charges accumulated on a surface of a sample according to the positive voltage applied by the voltage supply unit, the bias unit being disposed between the end of the column unit and the sample stage; and
a support unit configured to support the bias unit, the support unit having a first end connected to the bias unit, and a second end fixed on a portion of the chamber unit.

12. The scanning electron microscope of claim 11, wherein the support unit comprises:
a first support having a first end connected to the bias unit and a second end; and
a second support having a first end fixed on a portion of the chamber unit, and a second end into which the second end of the first support is inserted such that the first support inserted into the second support is capable of sliding upward and downward along the second support.

13. The scanning electron microscope of claim 12, wherein
the first support includes a plurality of first height adjustment holes formed longitudinally in upper portion of the first support; and
the second support includes a plurality of second height adjustment holes formed longitudinally in lower portion of the second support to correspond to, and overlap with, the plurality of first height adjustment holes.

14. The scanning electron microscope of claim 13, wherein the height adjustment unit includes a height fastener configured to fix a position of the first support to a position of the second support while passing through a first adjustment hole and a second adjustment hole, the first adjustment hole being one of the plurality of first height adjustment holes, the second adjustment hole being one of the plurality of second height adjustment holes.

15. The scanning electron microscope of claim 14, wherein the height fastener includes a bolt, a screw, or a stud.

16. The scanning electron microscope of claim 12, wherein
the first and second supports are electrically connected to a control unit, and
the control unit is configured to control a distance of the bias unit from the sample stage by controlling the sliding of the first support with respect to the second support.

17. A scanning electron microscope (SEM) comprising:
a sample stage configured to hold a sample;
a column unit configured to generate an electron beam such that the electron beam irradiates the sample;
a detection unit configured to detect first signals, the first signals being signals emitted from the sample in response to the irradiation; and
a charge collecting unit configured to collect first charges, the first charges being charges accumulated on a surface of the sample, the charge collecting unit being disposed between the sample stage and the column unit.

18. The SEM of claim 17, further comprising:
a voltage supply unit configured to apply a voltage to the charge collecting unit, the charge collecting unit being configured to collect the first charges based on the applied voltage.

19. The SEM of claim 17, further comprising:
a chamber unit attached to the column unit, the chamber unit including the sample stage, the sample stage being spaced apart from an end of the column unit such that the sample can fit in between the column unit and the sample stage.

20. The SEM claim 17, wherein the charge collecting unit comprises:
a bias unit configured to collect the first charges, the bias unit being located between an end of the column unit and the sample stage; and
a support unit configured to support the bias unit, the support unit having a first end connected to the bias unit, and a second end connected to at least one of the chamber unit and the column unit, the support unit being configured to have an adjustable length such that distance between the bias unit and sample stage is adjustable.
